(19) United States
(12) Patent Application Publication
(10) Pub. No.: US 2014/0261627 A1
(43) Pub. Date: Sep. 18, 2014

(54) POWER AUGMENTATION IN CONCENTRATOR PHOTOVOLTAIC MODULES BY COLLECTION OF DIFFUSE LIGHT

(71) Applicant: Semprius, Inc., Durham, NC (US)

(72) Inventors: Matthew Meitl, Durham, NC (US); Joseph Carr, Chapel Hill, NC (US); Kevin Schneider, Cary, NC (US)

(73) Assignee: Semprius, Inc., Durham, NC (US)

(21) Appl. No.: 14/211,262

(22) Filed: Mar. 14, 2014

Related U.S. Application Data
(60) Provisional application No. 61/782,622, filed on Mar. 14, 2013.

(51) Int. Cl. H01L 31/052

(52) U.S. Cl. CPC H01L 31/0524
USPC 136/246; 438/69

(57) ABSTRACT

A concentrator-type photovoltaic module includes a backplane substrate, a plurality of concentrator photovoltaic (CPV) receivers on a surface of the backplane substrate, and concentrating optics positioned over the surface of the backplane substrate and configured to focus on-axis incident light onto the CPV receivers. A plurality of non-concentrator photovoltaic (PV) cells are provided on the surface of the backplane substrate. The PV cells are positioned to receive light that passes off-axis through the concentrating optics. Related devices and methods are also discussed.

### CLAIM OF PRIORITY

This application claims priority to U.S. provisional patent application No. 61/782,622 entitled “POWER AUGMENTATION IN CONCENTRATOR PHOTOVOLTAIC MODULES BY COLLECTION OF DIFFUSE LIGHT” filed on Mar. 14, 2013, the disclosure of which is incorporated by reference herein in its entirety.

### FIELD

The present invention relates to solar photovoltaic power generation, and more particularly, to concentrated photovoltaic (CPV) power generation.

### BACKGROUND

Concentrator photovoltaics (CPV) is an increasingly promising technology for renewable electricity generation in sunny environments. CPV uses relatively inexpensive, efficient optics to concentrate sunlight onto solar cells, thereby reducing the cost requirements of the semiconductor material and enabling economic use of efficient cells, for example multi junction solar cells. This high efficiency at reduced costs, in combination with other aspects, makes CPV among the more economical renewable solar electricity technology in sunny climates and geographic regions.

Concentrator photovoltaic solar cell systems may use lenses or mirrors to focus a relatively large area of sunlight onto a relatively small solar cell. The solar cell can convert the focused sunlight into electrical power. By optically concentrating the sunlight into a smaller area, fewer and smaller solar cells with greater conversion performance can be used to create more efficient photovoltaic systems at lower cost.

For example, CPV module designs that use small solar cells (for example, cells that are smaller than about 4 mm²) may benefit significantly because of the ease of energy extraction from such cells. The superior energy extraction characteristics can apply to both usable electrical energy and waste heat, potentially allowing a better performance-to-cost ratio than CPV module designs that use larger cells. To increase or maximize the performance of concentrated photovoltaic systems, CPV systems can be mounted on a tracking system that aligns the CPV system optics with a light source (typically the sun) such that the incident light is substantially parallel to an optical axis of the concentrating optical elements, to focus the incident light onto the photovoltaic elements.

### SUMMARY

According to some embodiments of the present invention, a concentrator-type photovoltaic module includes a backplane; a plurality of concentrator photovoltaic (CPV) receivers on the backplane; concentrating optics positioned over the backplane and configured to focus on-axis incident light onto said CPV receivers; and a plurality of non-concentrator photovoltaic (PV) cells on the backplane, wherein said PV cells are configured to capture diffuse light and convert at least a portion of the non-direct solar EM radiation that passes off-axis through the concentrating optics into electricity.

According to further embodiments of the present invention, a method of fabricating a concentrator-type photovoltaic module with augmented power due to photovoltaic (PV) cells that capture diffuse light, includes: providing a backplane substrate having electrical interconnection features; assembling a sub-array of concentrator photovoltaic (CPV) receivers onto said backplane using surface mount technology; assembling a sub-array of photovoltaic (PV) cells configured to capture diffuse light onto said backplane using surface mount technology; and joining said sub-arrays to concentrating optical elements such that the concentrating optical elements focus direct sunlight onto the CPV receivers and allow non-direct solar EM radiation to fall on the PV cells that capture diffuse light.

According to still further embodiments of the present invention, a method of fabricating a concentrator-type photovoltaic module with augmented power due to photovoltaic (PV) cells that capture diffuse light, includes: providing a backplane substrate having electrical interconnection features; assembling a sub-array of concentrator photovoltaic (CPV)receivers onto said backplane using surface mount technology; overlaying a sub-array of interconnected PV cells onto said backplane so that the sub-array covers a portion of the backplane that is not occupied by the CPV receivers without obscuring concentrated direct sunlight from absorption by the CPV receivers; and joining said sub-arrays to concentrating optical elements such that the concentrating optical elements focus direct sunlight onto the CPV receivers and allow non-direct solar EM radiation to fall on the PV cells that capture diffuse light.

Other methods and/or devices according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

Aspects of the present disclosure are illustrated by way of example and are not limited by the accompanying figures with like references indicating like elements.

FIG. 1 is a block diagram illustrating a CPV module according to some embodiments of the present invention.

FIG. 2 is a block diagram illustrating a CPV module according to further embodiments of the present invention.

FIGS. 3A-B and 4 illustrate example circuits according to some embodiments of the present invention that interconnect an array of CPV receivers and PV cells that collect diffuse light.

FIGS. 5A and 5B are graphs illustrating simulated operating characteristics of CPV modules including sub-arrays similar to those illustrated in FIGS. 3A-B and 4 according to some embodiments of the present invention.

FIG. 6 is a cross sectional view of a CPV module illustrating example concentrating optics according to some embodiments of the present invention.

### DETAILED DESCRIPTION

Some embodiments of the present invention may arise from realization that, in a backplane including CPV receivers thereon, off-axis regions may be used to augment the power of CPV modules. As described herein, light rays that propagate substantially parallel to the optical axis of an optical element are considered ‘on-axis’ light rays, and light rays that do not propagate substantially parallel to the optical axis of the optical element are considered ‘off-axis’.

Embodiments of the present invention thus arrange photovoltaic (PV) elements or cells on the backplane to capture off-axis or diffuse light, which may otherwise not be absorbed by the CPV receivers on the backplane. In particular, some embodiments of the present invention provide a CPV module that includes optical concentrators, CPV receivers, photovoltaic (PV) cells that capture diffuse light, and a backplane with electrical interconnection features. The optical concentrators concentrate at least a portion of the direct solar electromagnetic (EM) radiation onto the CPV receivers. The CPV receivers efficiently convert the direct solar EM radiation into electricity. At least a portion of the non-direct (e.g. global or scattered) EM solar radiation falls or is otherwise directed to PV cells that are arranged, positioned, and/or otherwise configured to capture diffuse light. The PV cells that capture diffuse light convert non-direct EM solar radiation into electricity. The backplane provides mechanical support and control of spatial orientation for the CPV receivers and the PV cells that capture diffuse light. The backplane further provides electrical interconnection for combining electrical output of the CPV receivers and the PV cells that capture diffuse light.

Embodiments of the present invention may thus provide a mechanism for improving the efficiency of solar photovoltaic modules, especially in clear-sky, sunny conditions. Embodiments of the present invention may also provide a mechanism for significantly increasing the output of CPV modules in hazy conditions. Some configurations of concentrating optics in accordance with embodiments of the present invention are described in commonly-assigned U.S. patent application Ser. No. 13/700,411 to Meitl et al. entitled “PHOTOVOLTAIC DEVICES WITH OFF-AXIS IMAGE DISPLAY”, the disclosure of which is incorporated by reference herein in its entirety. For example, FIG. 1 of U.S. patent application Ser. No. 13/700,411, reproduced below as FIG. 6 (with unused reference designators deleted), illustrates a configuration of concentrating optics 40 in accordance with some embodiments of the present invention.

Some embodiments of the present invention may simultaneously provide several advantages. For example, CPV modules in accordance with some embodiments of the present invention may generate more power than some conventional CPV modules, and may generate significantly more power than such conventional CPV modules under bright, hazy conditions.

Some embodiments of the present invention are illustrated with reference to FIGS. 1-5. FIG. 1 illustrates a CPV module 100 according to some embodiments of the present invention that uses large (>0.1 m) silicon cells 105 that have holes or window structures 101 through which direct sunlight may be focused onto CPV receivers 110, each of which may include a solar cell having a light-receiving surface area of about 4 mm² or less, as well as concentrating optical elements, associated support structures, and conductive structures for electrical connection to a backplane 115 or other common substrate. In FIG. 1, the silicon solar cells 105 are the PV cells that capture diffuse light. As such, the PV cells 105 may define surface areas that are one or more orders of magnitude greater than those of the CPV receivers 110. However, the PV cells 105 may not be positioned or otherwise arranged such that light from the concentrating optics is concentrated thereon.

In particular, FIG. 1 illustrates a CPV backplane 115 that includes 660 CPV receivers 110 and 12 silicon solar cells 105. The CPV receivers 110 are illustrated as spheres by way of example in FIG. 1, and are positioned in openings or holes 101 in the silicon cells 105. The CPV receivers 110 are configured to convert direct (e.g., on-axis) sunlight A into electricity, and the silicon cells 105 are configured to convert diffuse (e.g., off-axis) light B into electricity. The concentrating optics 40 are shown by way of example in FIG. 6; however, it will be understood that in some embodiments the concentrating optics may further include a secondary lens element (for example, placed or otherwise positioned on or adjacent to the light receiving surface of the solar cell of each CPV receiver 110), and a primary lens element (for example, a Fresnel lens 42, a plano-convex lens, a double-convex lens, a crossed panoptic lens, and/or arrays thereof) that may be positioned over the secondary lens element to direct incident light thereto.

FIG. 2 illustrates a CPV module 200 according to some embodiments of the present invention in which small (<0.1 m) cells 205 are positioned between CPV receivers 210 on a backplane 215. Each of the CPV receivers 210 may include a solar cell having a light-receiving surface area of about 4 mm² or less, as well as concentrating optical elements, associated support structures, and conductive structures for electrical connection to a backplane 215 or other common substrate. In FIG. 2, the silicon solar cells 205 are the PV cells that capture diffuse light. As such, the PV cells 205 may define surface areas that are one or more times greater than those of the CPV receivers 210. However, the PV cells 205 may not be positioned or otherwise arranged such that light from the concentrating optics is concentrated thereon.

In particular, the CPV backplane 215 includes 660 CPV receivers 210 and 609 silicon solar cells 205. The CPV receivers 210 are illustrated as spheres by way of example in FIG. 2. The CPV receivers 210 are configured to convert direct (e.g., on-axis) sunlight A into electricity, and the silicon cells 205 are configured to convert diffuse (e.g., off-axis) light B into electricity. The concentrating optics 40 are shown by way of example in FIG. 6; however, it will be understood that in some embodiments the concentrating optics 40 may further include a secondary lens element (for example, placed or otherwise positioned on or adjacent to the light receiving surface of the solar cell of each CPV receiver 210), and a primary lens element (for example, a Fresnel lens 42, a plano-convex lens, a double-convex lens, a crossed panoptic lens, and/or arrays thereof) that may be positioned over the secondary lens element to direct incident light thereto.

FIGS. 3A-B and 4 illustrate examples of circuits according to some embodiments of the present invention that interconnect an array of CPV receivers 310 and PV cells 305 that collect diffuse light. In these examples, the individual CPV receivers 310 operate at slightly less than twice the voltage of individual PV cells 305 that collect diffuse light. It will be understood that these properties are described by way of example to illustrate the concepts of the present invention, and are not intended to limit the scope of the invention.

In particular, FIGS. 3A and 3B are schematic circuit diagrams illustrating two sub-arrays 300a and 300b according to some embodiments of the present invention. On the left, FIG. 3A illustrates a sub-array 300a of CPV receivers 310. On the right, FIG. 3B illustrates a sub-array 300b of PV cells 305 that capture diffuse light. The two sub-arrays 300a and 300b of FIGS. 3A-3B are designed or otherwise configured to be approximately matched in voltage, where the sub-array 300b of PV cells 305 that capture diffuse light shown in FIG. 3B are configured to operate at a slightly higher voltage than the sub-array 300a of CPV receivers 310 shown in FIG. 3A.

The 24 CPV receivers 310 in these examples are arranged in a series connection of six blocks, each block including four CPV receivers 310 wired together in parallel with a bypass diode 320. The resulting sub-array 300a shown in FIG. 3A, in this example, operates at approximately six times the voltage of an individual CPV receiver 310. The sub-array 300b of PV cells 305 that capture diffuse light shown in FIG. 3B are arranged in a series connection of 12 blocks, with each block including two PV cells 305 that capture diffuse light wired together in parallel with a bypass diode 320. This second sub-array 300b shown in FIG. 3B, in this example, operates at a voltage that is slightly higher than the first sub-array 300a.

The two sub-arrays 300a and 300b of FIGS. 3A and 3B may be spatially arranged to overlap in a module 400, as illustrated in FIG. 4. The two sub-arrays 300a and 300b of FIGS. 3A and 3B may also be electrically interconnected in parallel. In addition, blocking diodes may be used to maintain voltage in the array in the event that one of the sub-arrays 300a, 300b loses capacity to generate high voltages.

FIGS. 5A and 5B are graphs illustrating simulated operating characteristics of CPV modules including sub-arrays similar to those illustrated in FIGS. 3A-B and 4 according to some embodiments of the present invention. In particular, FIG. 5A illustrates current-voltage (I-V) characteristics for a CPV module including PV cells that capture diffuse light in comparison with I-V characteristics of the CPV receivers and PV cells alone, while FIG. 5B illustrates power-voltage (P-V) characteristics for a CPV module including PV cells that capture diffuse light in comparison with P-V characteristics of the CPV receivers and PV cells alone. As shown in FIGS. 5A and 5B, by employing PV cells to capture diffuse or off-axis light, the modules in accordance with embodiments of the present invention provide improved I-V and P-V characteristics (versus the CPV receivers alone) over the entire operating range.

In some embodiments, one or more CPV modules according to embodiments of the present invention can be mounted on a support for use with a multi-axis tracking system. The tracking system may be controllable in one or more directions or axes to align the CPV receivers with incident light at a normal (e.g., on-axis) angle to increase efficiency. In other words, the tracking system may be used to position the CPV modules such that incident light (for example, sunlight) is substantially parallel to an optical axis of the optical element(s) that focus the incident light onto the CPV receivers. Because a tracked system can change its orientation through the day to follow the location of the sun, a viewer at a single location may observe the CPV modules at an off-axis angle, such that the PV elements or cells (rather than the CPV receivers) are visible. In an alternative arrangement, the CPV modules can have a fixed location and/or orientation whereby, if viewed from an off-axis angle, the PV elements or cells may likewise be visible.

In some embodiments of the present invention, the PV cells that capture diffuse light can include cadmium telluride and/or alloys thereof In some embodiments of the present invention, the PV cells that capture diffuse light can include amorphous silicon and/or alloys thereof. In some embodiments of the present invention, the PV cells that capture diffuse light can include copper indium gallium selenide and/or alloys thereof

In some embodiments, the CPV receivers can be connected to the backplane by surface mount technology.

In some embodiments, the PV cells that capture diffuse light can include heterostructure solar cells.

In some embodiments, the CPV receivers can be organized into first sub-arrays, the PV cells that capture diffuse light can be organized into second sub-arrays, and the first and second sub-arrays can be connected in parallel. In some embodiments, sub-arrays of CPV receivers can be approximately current matched to sub-arrays of PV cells that capture diffuse light. In some embodiments, the sub-arrays of PV cells that capture diffuse light can operate at a slightly higher voltage than the sub-arrays of CPV receivers. In some embodiments, the sub-arrays of PV cells that capture diffuse light can operate at a slightly higher current than the sub-arrays of CPV receivers.

In some embodiments, the PV cells that capture diffuse light can include holes through which focused direct sunlight can pass to the CPV receivers.

The present invention has been described above with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In no event, however, should “on” or “directly on” be construed as requiring a layer to cover an underlying layer.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an ” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments of the present invention described herein, and of the manner and process of making and using them, and shall support claims to any such combination or subcombination.

In some embodiments, the PV cells that capture diffuse light can include crystalline silicon, monocrystalline silicon, polycrystalline silicon, and/or multicrystalline silicon.

In the specification, there have been disclosed embodiments of the invention and, although specific terms are employed, they are used in a generic and descriptive sense only and not for purposes of limitation, the scope of the present invention, being set forth in the following claims.

1. (canceled)

2. A concentrator-type photovoltaic module, comprising:
a backplane substrate;
a plurality of concentrator photovoltaic (CPV) receivers on a surface of the backplane substrate;
concentrating optics positioned over the surface of the backplane substrate and configured to focus on-axis incident light onto the CPV receivers; and
a plurality of non-concentrator photovoltaic (PV) cells on the surface of the backplane substrate between ones of the CPV receivers, wherein the PV cells are configured positioned to receive light that passes off-axis through the concentrating optics.

3. A method of fabricating a concentrator-type photovoltaic module, the method comprising:
providing a backplane substrate having electrical interconnection features;
assembling a sub-array of concentrator photovoltaic (CPV) receivers onto the backplane substrate using surface mount technology;
assembling a sub-array of non-concentrator photovoltaic (PV) cells configured to capture diffuse light onto the backplane substrate using surface mount technology; and
positioning one or more concentrating optical elements over the backplane substrate, wherein the concentrating optical elements are configured to focus on-axis incident light onto the CPV receivers and allow off-axis incident light to fall on the PV cells.

4. The method of claim 3, wherein assembling the sub-array of non-concentrator PV cells comprises:
overlaying the sub-array of interconnected of non-concentrator PV cells onto the surface of the backplane substrate so that the sub-array of non-concentrator PV cells extends on a portion of the surface of the backplane substrate that is not occupied by the CPV receivers without obscuring the CPV receivers from the on-axis incident light.

5. The module of claim 2, wherein the CPV receivers comprise solar cells having respective surface areas of about 4 square millimeters (mm²) or less, and wherein the PV cells have respective surface areas greater than those of the CPV receivers by one or more orders of magnitude.

6. The module of claim 5, wherein the PV cells have respective dimensions of greater than about 0.1 meter (m) and respectively include windows or openings therein that expose ones of the CPV receivers to the incident light.

7. The module of claim 5, wherein the PV cells have respective dimensions of less than about 0.1 meter (m), and wherein respective ones of the PV cells are positioned between adjacent ones of the CPV receivers.

8. The module of claim 5, wherein the CPV receivers define a first sub-array on the surface of the backplane substrate, and wherein the PV cells define a second sub-array on the surface of the backplane substrate that does not obscure the CPV receivers of the first sub-array from the on-axis incident light.

9. The module of claim 8, wherein the backplane substrate comprises electrical interconnections that combine electrical outputs of the CPV receivers and the PV cells.

10. The module of claim 9, wherein the first sub-array of the CPV receivers is connected in parallel with the second sub-array of the PV cells.

11. The module of claim 8, wherein the first and second sub-arrays are approximately matched with respect to operating voltage.

12. The module of claim 8, wherein the second sub-array of the PV cells is configured to operate at a higher voltage and/or a higher current than the first sub-array of the CPV receivers.

13. The module of claim 5, wherein the PV cells are arranged on the surface of the backplane substrate such that the on-axis incident light is not concentrated thereon.

14. The module of claim 2, wherein the concentrating optics comprise a Fresnel lens, a plano-convex lens, a double-convex lens, a crossed panoptic lens, and/or arrays thereof.

15. The module of claim 2, wherein the module is mounted on a multi-axis tracking system that is controllable in one or more directions or axes to position the module such that respective optical axes of the concentrator optics are aligned substantially parallel to the incident light.

16. The module of claim 2, wherein the PV cells comprise cadmium telluride, amorphous silicon, or copper indium gallium selenide, and/or alloys thereof.

17. The module of claim 2, wherein the PV cells comprise heterostructure solar cells.

18. A photovoltaic device, comprising:
a substrate including a concentrator photovoltaic element and at least one non-concentrator photovoltaic element electrically connected thereto arranged alongside one another on a surface of the substrate, wherein the non-concentrator photovoltaic element has a surface area that is greater than that of the concentrator photovoltaic element by one or more orders of magnitude; and
a concentrating optical element positioned over the surface of the substrate to concentrate incident light propagating on-axis with respect to an optical axis thereof onto the concentrator photovoltaic element, and to allow light propagating off-axis with respect to the optical axis thereof onto the non-concentrator photovoltaic element.

19. The device of claim 18, wherein:
the concentrator photovoltaic element comprises one of a plurality of concentrator photovoltaic elements arranged in a first sub-array on the surface of the substrate;
the non-concentrator photovoltaic element comprises one of a plurality of non-concentrator photovoltaic elements arranged in a second sub-array on the surface of the substrate alongside the first sub-array so as not to obstruct the concentrator photovoltaic elements thereof; and
the substrate includes a plurality of electrical connections that couple the first and second sub-arrays in parallel.

20. The device of claim 19, wherein the non-concentrator photovoltaic elements respectively include windows or openings therein that expose ones of the concentrator photovoltaic elements to the incident light.

21. The device of claim 19, wherein respective ones of the non-concentrator photovoltaic elements are positioned between adjacent ones of the concentrator photovoltaic elements.
